(19) United States
(12) Patent Application Publication
(10) Pub. No.: US 2009/0161324 A1
(43) Pub. Date: Jun. 25, 2009

(54) SHIELDING CASE, WIRING BOARD AND ELECTRONIC MODULE

(75) Inventors: Noriaki Sakamoto, Fukaya-shi (JP); Masahiro Kobayashi, Kazo-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/210,931

(22) Filed: Sep. 15, 2008

(30) Foreign Application Priority Data
Dec. 25, 2007 (JP) 2007-332038

(51) Int. Cl. H05K 9/00; H05K 7/00

(52) U.S. Cl. 361/728; 361/816

(57) ABSTRACT

A shielding case for accommodating a wiring board includes a board mounting member with a fitting member formed at an outer frame thereof so that the wiring board is fixed and held to the board mounting member through fitting of the fitting member into a through hole formed at the wiring board.

### CROSS-REFERENCE TO RELATED APPLICATIONS

This application is based upon and claims the benefit of priority from the prior Japanese Patent Application No. 2007-332038, filed on Dec. 25, 2007; the entire contents of which are incorporated herein by reference.

### BACKGROUND OF THE INVENTION

1. Field of the Invention

The present invention relates to a shielding case of an electronic module which is incorporated in an electronic main instrument such as a television receiver or a receiver such as a set-top box, a wiring board preferably usable for the shielding case and the electronic module, e.g., containing the shielding case and the wiring board.

2. Description of the Related Art

An electronic instrument such as an electronic tuner is incorporated in a receiver such as a set-top box or an electronic main instrument such as a television receiver. In this case, the wiring board of the electronic instrument is accommodated in a shielding case so that an electronic component and/or an integrated circuit element mounted on the wiring board is not affected by external electronic wave and then, operated stably.

The shielding case includes a board mounting member which is shaped in frame and made of metallic plate, and the wiring board with electronic components, connectors and the like thereon is mounted on the board mounting member to form an assembly. Moreover, a top casing member and a bottom casing member made of metallic plate and shaped in plate are also attached to the board mounting member.

Recently, on the other hand, it is required that an electronic component such as an electronic tuner is required to be enhanced and diversified in inherent function, and to be downsized and thinned. In this point of view, it is also required that the electronic module relating to the electronic component is downsized and thinned and the shielding case to be incorporated into the electronic module is downsized and thinned.

Some fitting members shaped in convex are provided in the frame of the board mounting member so as to be intruded and fitted into the corresponding through holes formed at the wiring board and soldered with the wiring board so that the wiring board can be fixed and held to the board mounting member. Since the through holes are formed corresponding to the fitting members, the through holes result in being formed in the inner area, that is, the wiring pattern area and the land area for mounting some electronic components (refer to Reference 1). In view of the inherent use and function of the wiring pattern area and the land area, therefore, it is desired to decrease the number of through hole.

In contrast, the wiring board can not be fixed tightly with the board mounting member as the number of through hole is decreased. In this point of view, the number of through hole must be increased to some degrees, so that the area for the through holes to be formed must be formed at the wiring board independently from the wiring pattern area and the land area. As a result, the wiring board is enlarged so that the shielding case and the electronic module are also enlarged, which is contrary to the above-described requirement for downsizing and thinning the circuit boards.

The fitting members of the board mounting member are electrically and mechanically connected with the GND pattern of the wiring board by means of soldering so that the GND electric potential of the GND pattern can be sufficiently secured and thus, the shield property of the shielding case can be sufficiently secured. In this point of view, therefore, it is desired to increase the number of contacting point between the fitting members and the GND pattern and thus, increase the number of through hole. In view of the shield property of the shielding case, therefore, the wiring board is required to be enlarged, which is contrary to the above-described requirement for downsizing and thinning the circuit boards.

In view of securing the fixing and holding of the wiring board to the board mounting member and securing the shield property of the shielding case containing the board mounting member, therefore, the recent requirement of downsizing and thinning the electronic components can not be satisfied.

[Reference 1] JP-U 3132913 (Japanese Utility-Model Registration)

### BRIEF SUMMARY OF THE INVENTION

It is an object of the present invention to enhance the fixing and holding of a wiring board to a board mounting member and enhance the shield property of a shielding case containing the board mounting member while an electronic module is downsized and thinned.

In order to achieve the above object, an aspect of the present invention relates to a shielding case for accommodating a wiring board, including a board mounting member with a fitting member formed at an outer frame thereof so that the wiring board is fixed and held to the board mounting member through fitting of the fitting member into a through hole formed at the wiring board.

Another aspect of the present invention relates to a wiring board to be fixed and held into a shielding case, wherein a through hole to be fitted with a fitting member provided at the shielding case is formed at a peripheral edge of the wiring board.

Still another aspect of the present invention relates to an electronic module, including: a wiring board where a through hole is formed at a peripheral edge thereof; and a board mounting member with a fitting member formed at an outer frame thereof, wherein the wiring board is fixed and held to the board mounting member through fitting of the fitting member into the through hole.

According to the aspects of the present invention can be enhance the fixing and holding of a wiring board to a board mounting member and enhance the shield property of a shielding case containing the board mounting member while an electronic module is downsized and thinned.

### BRIEF DESCRIPTION OF THE SEVERAL VIEWS OF THE DRAWINGS

FIG. 1 is a structural view schematically showing a board mounting member of a shielding case according to a first embodiment.

FIG. 2 is a perspective view schematically showing a wiring board according to the first embodiment.

FIG. 3 is a schematic view showing the fabrication process of an assembly made of the board mounting member shown in FIG. 1 and the wiring board shown in FIG. 2.

FIG. 4 is an enlarged view showing the fitted portion between the board mounting member shown in FIG. 1 and the wiring board shown in FIG. 2.

FIG. 5 is a structural view schematically showing a board mounting member of a shielding case according to a second embodiment.

FIG. 6 is a perspective view schematically showing the wiring board according to a third embodiment.

FIG. 7 is a schematic view showing the fabrication process of an assembly made of the board mounting member shown in FIG. 1 and the wiring board shown in FIG. 6.

FIG. 8 is an enlarged view showing the fitted portion between the board mounting member shown in FIG. 1 and the wiring board shown in FIG. 6.

FIG. 9 is a structural view schematically showing a board mounting member of a shielding case according to a fourth embodiment.

FIG. 10 is a perspective view schematically showing a wiring board according to the fourth embodiment.

FIG. 11 is a schematic view showing the fabrication process of an assembly made of the board mounting member shown in FIG. 9 and the wiring board shown in FIG. 10.

FIG. 12 is a schematic view showing the fabrication process of an assembly made of the board mounting member and wiring board according to the first embodiment, and the top casing member and the bottom casing member.

FIG. 13 is a perspective view schematically showing a shielding case according to an embodiment.

FIG. 14 is an enlarged view showing the fitting state between the board mounting member and the top and bottom case members of the shielding case shown in FIG. 13.

### DETAILED DESCRIPTION OF THE INVENTION

Hereinafter, the present invention will be described in detail with reference to the drawings.

### First Embodiment

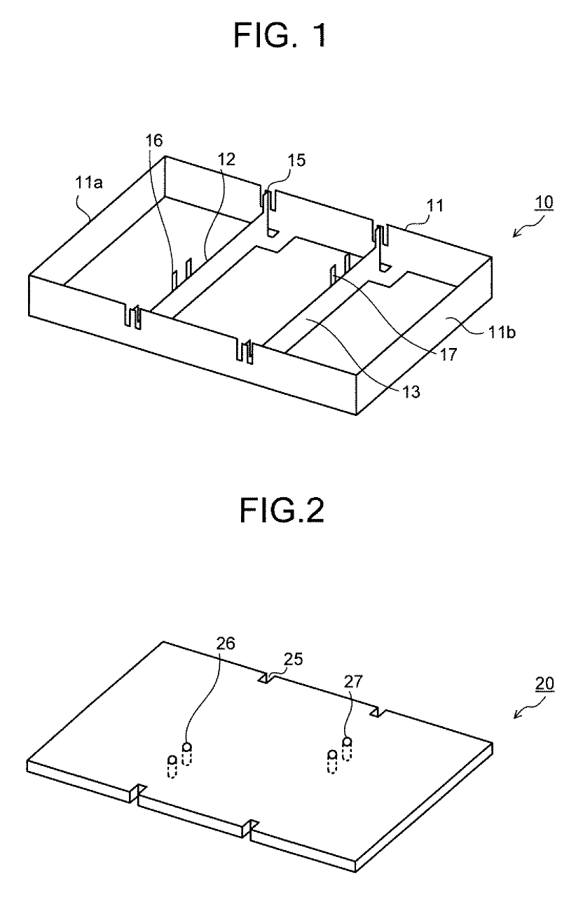

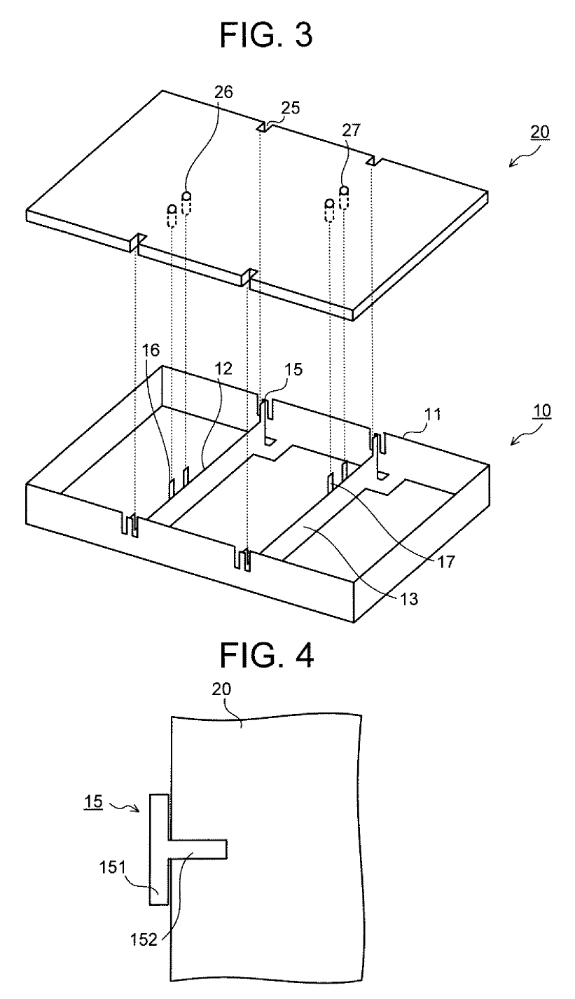

FIGS. 1 to 4 are explanatory views for this embodiment. FIG. 1 is a structural view schematically showing a board mounting member of a shielding case in this embodiment, and FIG. 2 is a perspective view schematically showing a wiring board according to the first embodiment. FIG. 3 is a schematic view showing the fabrication process of an assembly made of the board mounting member shown in FIG. 1 and the wiring board shown in FIG. 2, and FIG. 4 is an enlarged view showing the fitted portion between the board mounting member shown in FIG. 1 and the wiring board shown in FIG. 2. For simplification, a wiring pattern, an electronic component and the like are omitted in FIG. 2.

As will described hereinafter, in this embodiment, some of the fitting members to be provided in the inner side of the board mounting member is provided at the outer frame thereof.

As shown in FIG. 1, a board mounting member 10 includes a rectangular outer frame 11, and two beams 12 and 13 which are across the inner space in the width direction of the outer frame 11. In this embodiment, the beams 12 and 13 are provided so as to be almost parallel to the side surfaces 11a and 11b of the outer frame 11, but may be configured as occasion demands.

Then, four T-shaped fitting members are provided at the connections between the outer frame 11 and the beams 12, 13. Moreover, two convex fitting members 16 are provided at the left side of the beam 12 and two convex fitting members 17 are also provided at the right side of the beam 13.

As shown in FIG. 2, on the other hand, four through holes 25 are formed in slit at the peripheral edge of a wiring board 20, and two sets of through holes 26 and 27 are formed at the inner side of the wiring board 20. The through holes 25 are formed corresponding to the fitting members 15 of the board mounting member 10 and the through holes 26 are formed corresponding to the fitting members 16 of the board mounting member 10. Moreover, the through holes 27 are also formed corresponding to the fitting members 17 of the board mounting member 10.

In order to mount, fix and hold the wiring board 20 shown in FIG. 2 to the board mounting member 10 shown in FIG. 1, the fitting members 15 provided at the outer frame 11 of the board mounting member 10 are fitted into the through holes 25 formed at the peripheral edge of the wiring board 20, and the fitting members 16 provided at the beam 12 of the board mounting member 10 are fitted into the through holes 26 formed at the inner side of the wiring board 20, and the fitting members 17 provided at the beam 13 of the board mounting member 10 are fitted into the through holes 27 formed at the inner side of the wiring board 20. In this case, the fitting members 15 to 17 are soldered with the fitting portions and fixed into the through holes 25 to 27.

Since the fitting members 15 are formed in T-shape, in real, the convex portions 152 protruded from the corresponding base portions 151 in the fitting members 15 are fitted into the through holes 25 of the wiring board 20 as shown in FIG. 4.

In this embodiment, the four fitting members 15 are provided and the four fitting members 16 and 17 are additionally provided so that the number of fitting members is set to eight.

Conventionally, all of the eight fitting members are provided at the beams 12 and 13 located at the inner side of the outer frame 11 so that all of the eight through holes corresponding to the eight fitting members are also formed at the inner side of the wiring board 20. In this point of view, it is required to form the area for the eight through holes to be formed on the wiring board 20 so as not to deteriorate the wiring pattern area and the land area for mounting the electronic components.

In this embodiment, in contrast, only four through holes corresponding to the four fitting members provided at the beams 12 and 13 of the board mounting member 10 may be formed at the inner side of the wiring board 20. Accompanied by the formation of the four through holes in the inner side of the wiring board 20, only four soldering portions, not the eight soldering portions as the conventional fitting technique, may be formed at the inner side of the wiring board 20. In this point of view, the area for the through holes to be formed on the wiring board 20 in this embodiment can be narrowed in comparison with the conventional fitting technique. Moreover, since the four through holes formed corresponding to the four fitting members provided at the outer frame 11 are formed at the peripheral edge of the wiring board 20 beyond the wiring pattern area and the land area, no area for the four through holes to be formed is required.

In this embodiment, therefore, since the area for the four through holes, not the conventional eight through holes may be formed on the wiring board 20, the wiring board 20 can be downsized. As a result, the board mounting member 10 for fixing and holding the wiring board 20 can be downsized, and the shielding case containing the board mounting member 10 and the thus obtained electronic module can be also downsized.

Since the fitting members 15 provided at the outer frame 11 of the board mounting member 10 and the through holes 25 formed at the peripheral edge of the wiring board 20 are located beyond the wiring pattern area and the land area, the soldering area between each fitting member 15 and each through hole 25 can be increased as large as 1.5 times of the conventional soldering area. Therefore, since the strength in soldering between the board mounting member 10 and the wiring board 20 can be increased entirely, the wiring board 20 can be tightly fixed and held to the board mounting member 10.

Moreover, the fitting members 15 to 17 of the board mounting member 10 are electrically and mechanically connected with the GND pattern of the wiring board 20 so that the GND electric potential of the GND pattern can be ensured through the board mounting member 10. In this embodiment, since the soldered areas between the fitting members 15 provided at the outer frame 11 of the board mounting member 10 and the through holes 25 formed at the peripheral edge of the wiring board 20 are increased respectively, the electric contact areas of the respective fitting members 15 with the GND pattern are increased. Therefore, the GND electric potential of the GND pattern can be much ensured through the board mounting member 10 so that the shield property of the shielding case containing the board mounting member 10 can be enhanced.

In this embodiment, the number of beams is set to two, but may be set to any number in view of the size and the like of a wiring board to be fixed and the number of fitting members.

Moreover, the number of fitting members 15 is set to four and the number of fitting members 16 and 17 is set to two, but the number of fitting members 15 to 17 may be set to any number in view of the size and the like of the wiring board. In this embodiment, the fitting members 15 are formed at the connections between the outer frame 11 and the beams 12, 13, but may be formed at any portions as occasion demands. Moreover, the fitting members 15 may be formed in another shape except T-shape.

### Second Embodiment

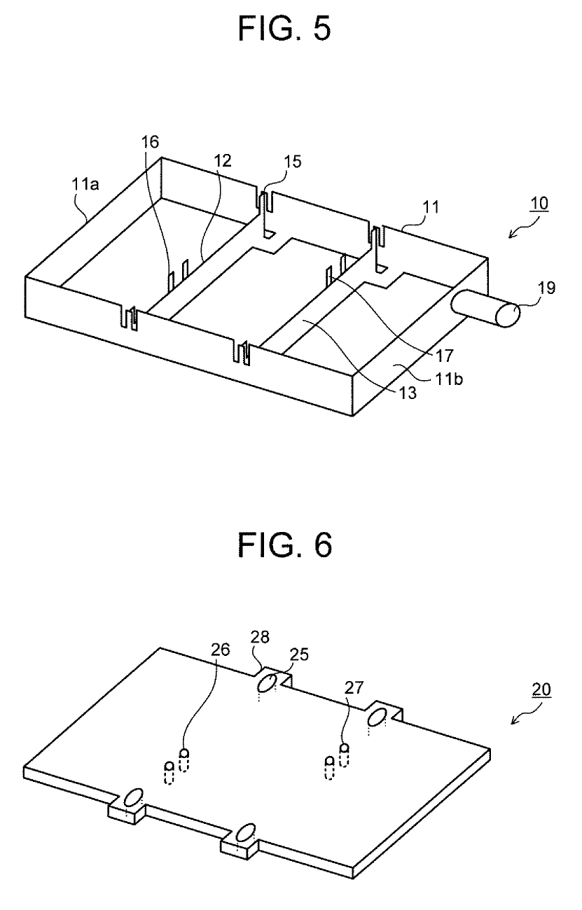

FIG. 5 is an explanatory view for this embodiment. FIG. 5 is a structural view schematically showing a board mounting member of a shielding case in this embodiment. Like or corresponding components are designated by the same reference numerals.

This embodiment is a modified embodiment of the first embodiment. This embodiment is different from the first embodiment except that an input connector 19 is provided at the side surface 11b of the board mounting member 11. In this embodiment, since the input connector 19 is provided, for example, a signal received at an antenna can be input into the wiring board via a given wiring cable. Namely, the shielding case in this embodiment can be applied for a receiver or the like.

Other components in this embodiment can be configured as the first embodiment, and thus, this embodiment can exhibit the same function/effect as the first embodiment.

The input connector 19 may be provided at the side surface 11a instead of the side surface 11b. Alternatively, two input connectors may be provided at both of the side surfaces 11a and 11b. Moreover, in this embodiment, the input connector 19 is provided at the right end of the side surface 11b, but may be provided at any portion thereof.

### Third Embodiment

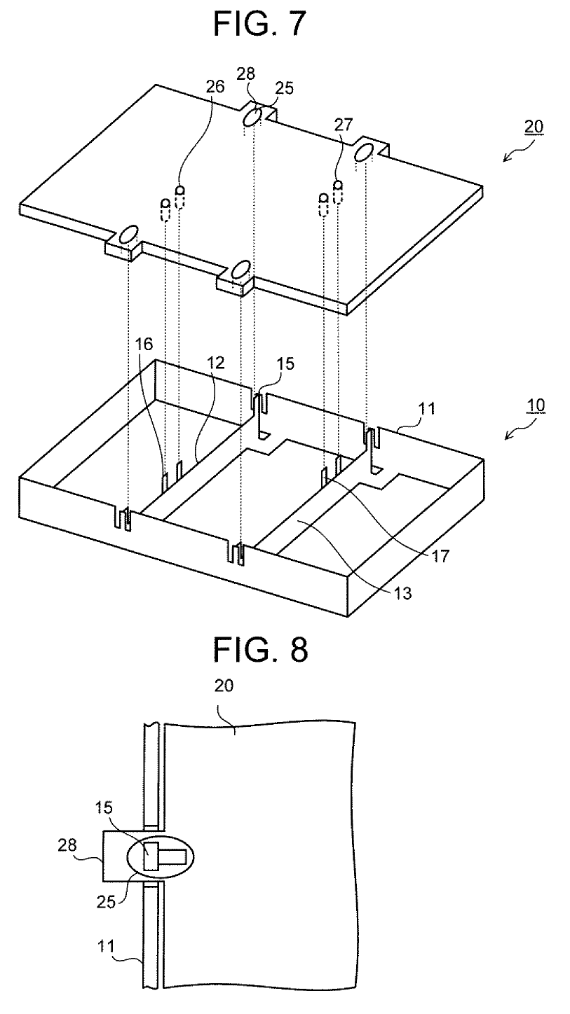

FIGS. 6 to 8 are explanatory views for this embodiment, FIG. 6 is a perspective view schematically showing the wiring board in this embodiment, and FIG. 7 is a schematic view showing the fabrication process of an assembly made of the board mounting member shown in FIG. 1 and the wiring board shown in FIG. 6. FIG. 8 is an enlarged view showing the fitted portion between the board mounting member and the wiring board. For simplification, a wiring pattern, an electronic component and the like are omitted in FIG. 6. Like or corresponding components are designated by the same reference numerals.

This embodiment is a modified embodiment of the first embodiment. This embodiment is different from the first embodiment except that the wiring board 20 includes four convex portions 28 at the peripheral edges thereof and four elliptical through holes 25 are formed at the corresponding convex portions 28 so as to be elongated from the inner side of the wiring board 20. Other components such as a board mounting member in this embodiment can be configured as the first embodiment.

In order to mount, fix and hold the wiring board 20 shown in FIG. 6 to the board mounting member 10 shown in FIG. 1, the fitting members 15 provided at the outer frame 11 of the board mounting member 10 are fitted into the through holes 25 formed at the peripheral edge of the wiring board 20, and the fitting members 16 provided at the beam 12 of the board mounting member 10 are fitted into the through holes 26 formed at the inner side of the wiring board 20, and the fitting members 17 provided at the beam 13 of the board mounting member 10 are fitted into the through holes 27 formed at the inner side of the wiring board 20. In this case, the fitting members 15 to 17 are also soldered with the fitting portions and fixed into the through holes 25 to 27.

The board mounting member 10 can be also fitted and fixed to the wiring board 20 via the elliptical through holes 25 formed at the convex portions 28 thereof, in substitution for the through holes 25 formed in slit as described in the above-embodiments. Therefore, this embodiment can exhibit the same function/effect as the first embodiment.

### Fourth Embodiment

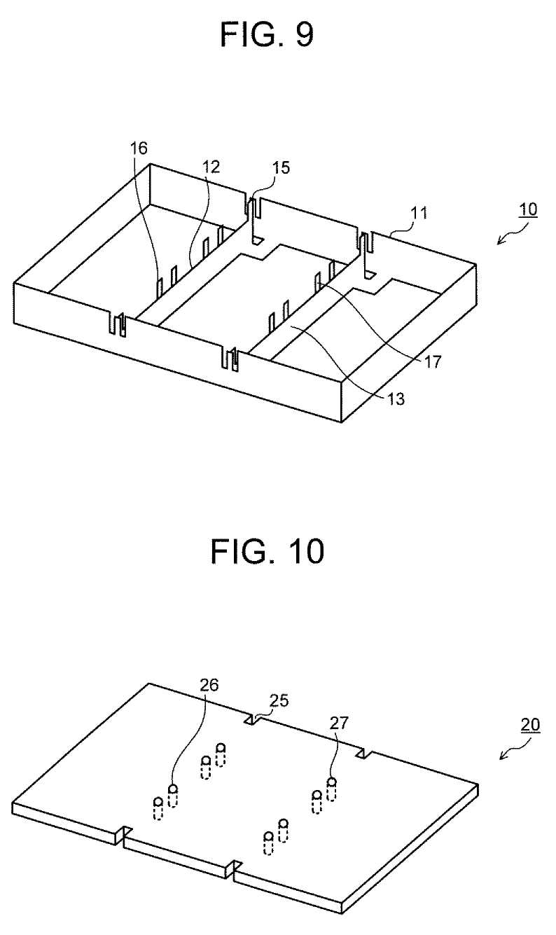

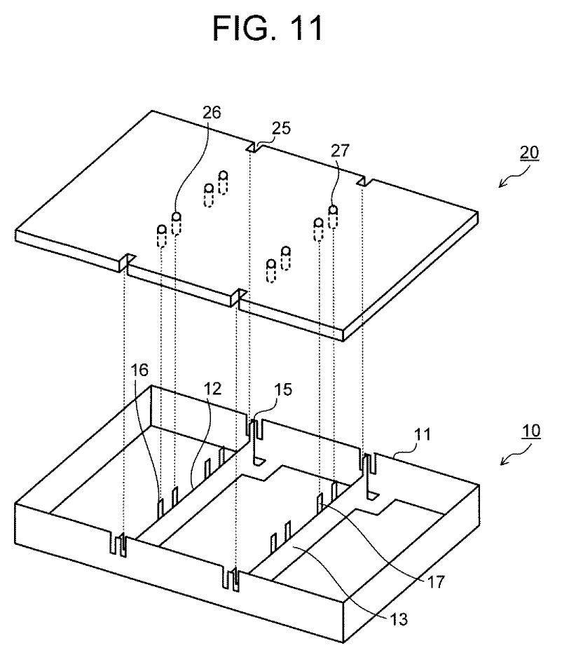

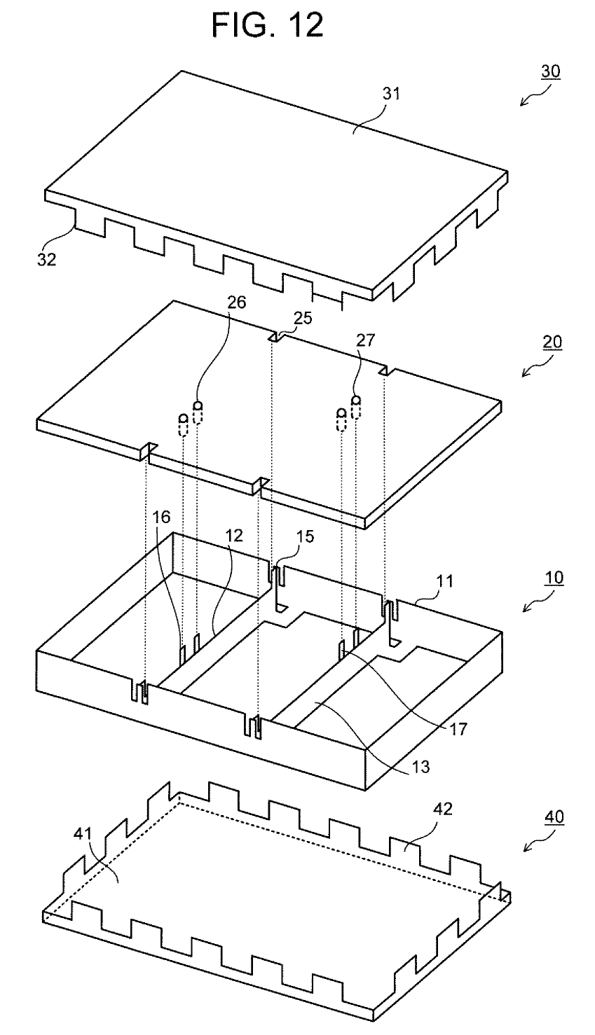

FIG. 9 is a structural view schematically showing a board mounting member of a shielding case in this embodiment, and FIG. 10 is a perspective view schematically showing a wiring board in this embodiment, and FIG. 11 is a schematic view showing the fabrication process of an assembly made of the board mounting member shown in FIG. 9 and the wiring board shown in FIG. 10. For simplification, a wiring pattern, an electronic component and the like are omitted in FIG. 10. Like or corresponding components are designated by the same reference numerals.

In this embodiment, additional fitting members are provided at the outer frame of the board mounting member in addition to the fitting members formed at the inner side thereof. The fitting members formed at the inner side of the board mounting member are inherently required for connecting between the board mounting member and the wiring board.

As shown in FIG. 9, the board mounting member 10 includes the rectangular outer frame 11, and the two beams 12 and 13 which are across the inner space in the width direction of the outer frame 11 along the top side surface and the bottom side surface thereof.

Then, four T-shaped convex fitting members are provided at the connections between the outer frame 11 and the beams 12, 13. Moreover, four convex fitting members 16 are provided at the beam 12 and four convex fitting members 17 are also provided at the beam 13.

As shown in FIG. 10, on the other hand, four through holes 25 are formed in slit at the peripheral edge of a wiring board 20, and four sets of through holes 26 and 27 are formed at the inner side of the wiring board 20. The through holes 25 are formed corresponding to the fitting members 15 of the board mounting member 10 and the through holes 26 are formed corresponding to the fitting members 16 of the board mounting member 10. Moreover, the through holes 27 are also formed corresponding to the fitting members 17 of the board mounting member 10.

In order to mount, fix and hold the wiring board 20 shown in FIG. 10 to the board mounting member 10 shown FIG. 9, the fitting members 15 provided at the outer frame 11 of the board mounting member 10 are fitted into the through holes 25 formed at the peripheral edge of the wiring board 20, and the fitting members 16 provided at the beam 12 of the board mounting member 10 are fitted into the through holes 26 formed at the inner side of the wiring board 20, and the fitting members 17 provided at the beam 13 of the board mounting member 10 are fitted into the through holes 27 formed at the inner side of the wiring board 20. In this case, the fitting members 15 to 17 are soldered with the fitting portions and fixed into the through holes 25 to 27, as shown in FIG. 11.

Since the fitting members 15 are formed in T-shape, the convex portions 152 protruded from the corresponding base portions 151 in the fitting members 15 are fitted into the through holes 25 of the wiring board 20 in the same manner as shown in FIG. 4.

In this embodiment, the four fitting members 15 are additionally provided for the inherent fitting members 16 and 17. Namely, the four fitting members 15 are added to the inherent eight fitting members 16 and 17. In this case, since the area for the through holes 26 and 27 to be formed can not be narrowed, the wiring board 20 can not be downsized so that the board mounting member 10, the shielding case containing the board mounting member 10 and the thus obtained electronic module can not be also downsized.

However, since the fitting members 15 provided at the outer frame 11 of the board mounting member 10 and the through holes 25 formed at the peripheral edge of the wiring board 20 are located beyond the wiring pattern area and the land area, soldering can be carried out at the areas around the through holes 25 in addition to the areas around the through holes 26 and 27 so that the fitting members 15 can be soldered with the through holes 25 while the fitting members 16 and 17 are soldered with the through holes 26 and 27. In this case, since the through holes 25 formed at the peripheral edge of the wiring board 20 are located beyond the wiring pattern area and the land area thereof, the soldering area between each fitting member 15 and each through hole 25 can be increased as large as 1.5 times of the conventional soldering area.

Therefore, since the strength in soldering between the board mounting member 10 and the wiring board 20 can be increased entirely, the wiring board 20 can be tightly fixed and held to the board mounting member 10.

Moreover, the fitting members 15 to 17 of the board mounting member 10 are electrically and mechanically connected with the GND pattern of the wiring board 20 so that the GND electric potential of the GND pattern can be ensured through the board mounting member 10. In this embodiment, since the soldered areas between the fitting members 15 provided at the outer frame 11 of the board mounting member 10 and the through holes 25 formed at the peripheral edge of the wiring board 20 are increased respectively, the electric contact areas of the respective fitting members 15 with the GND pattern are increased. Moreover, the total number of soldered areas is increased by providing the fitting members 15 and forming the through holes 25 additionally. Therefore, the total electric contact area of the fitting members 15 to 17 with the GND pattern of the wiring board 20 is increased.

As a result, the GND electric potential of the GND pattern can be much ensured through the board mounting member 10 so that the shield property of the shielding case containing the board mounting member 10 can be enhanced.

### Fifth Embodiment

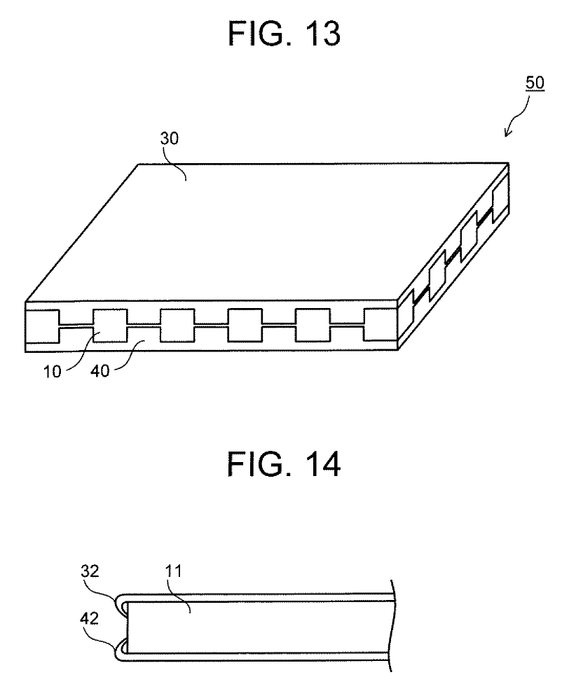

FIGS. 12 to 14 are explanatory views for this embodiment. FIG. 12 is a schematic view showing the state where the board mounting member 10 and the wiring board 20 in the first embodiment are fixed one another through the fitting and soldering as described above and then, covered with a top casing member 30 and a bottom casing member 40 to form a shielding case. FIG. 13 is a perspective view schematically showing the shielding case, and FIG. 14 is an enlarged view showing the fitting state between the board mounting member 10 and the top and bottom casing members 30, 40 of the shielding case shown in FIG. 13.

In this embodiment, as shown in FIG. 12, the top casing member 30 includes a plurality of engaging members 32 shaped like plate spring and elongated downward at the peripheral edge of a base portion 31 forming the bottom surface of the casing member 30, and the bottom casing member 40 includes a plurality of engaging members 42 shaped like plate spring and elongated upward at the peripheral edge of a base portion 41 forming the bottom surface of the casing member 40.

As shown in FIGS. 12 to 14, therefore, after the wiring board 20 is fixed and held to the board mounting member 10 to form an assembly, the top casing member 30 and the bottom casing member 40 are fixed and held to the assembly so that the engaging members 32 and 42 of the top casing member 30 and the bottom casing member 40 can be engaged with the outer surface of the outer frame 11 of the board mounting member 10, thereby forming a shielding case 50 as shown in FIG. 13.

The shielding case 50 may be used as an electronic module as it is, but may be appropriately connected with another external circuit board so as to form an intended electronic module.

Although the present invention was described in detail with reference to the above examples, this invention is not limited to the above disclosure and every kind of variation and modification may be made without departing from the scope of the present invention.

What is claimed is:

1. A shielding case for accommodating a wiring board, comprising a board mounting member with a fitting member formed at an outer frame thereof so that said wiring board is fixed and held to said board mounting member through fitting of said fitting member into a through hole formed at said wiring board.

2. The shielding case as set forth in claim 1,
wherein said board mounting member includes a beam formed across an inner space enclosed by said outer frame thereof and having an additional fitting member so that said wiring board is also fixed and held to said board mounting member through additional fitting of said additional fitting member into an additional through hole formed at said wiring board.

3. The shielding case as set forth in claim 1,
wherein said fitting member is formed in T-shape so as to contain a base portion and a convex portion protruded from said base portion so that said convex portion is fitted into said through hole.

4. The shielding case as set forth in claim 1,
further comprising a top casing member with a top engaging member and a bottom casing member with a bottom engaging member,
wherein said top casing member and said bottom casing member are fixed to said board mounting member through engagement of said top engaging member and bottom engaging member with an outer surface of said board mounting member.

5. A wiring board to be fixed and held into a shielding case,
wherein a through hole to be fitted with a fitting member provided at said shielding case is formed at a peripheral edge of said wiring board.

6. The wiring board as set forth in claim 5,
wherein an additional through hole to be fitted with an additional fitting member provided at said shielding case is formed at an inner side of said wiring board.

7. The wiring board as set forth in claim 5,
wherein said through hole is a slit formed at a peripheral edge of said wiring board.

8. The wiring board as set forth in claim 5,
further comprising a convex portion at a peripheral edge of said wiring board so that said through hole is formed elliptically at said convex portion so as to be elongated from an inner side of said wiring board.

9. An electronic module, comprising:
a wiring board where a through hole is formed at a peripheral edge thereof; and
a board mounting member with a fitting member formed at an outer frame thereof,
wherein said wiring board is fixed and held to said board mounting member through fitting of said fitting member into said through hole.

10. The electronic module as set forth in claim 9,
wherein said board mounting member includes a beam with an additional fitting member formed across an inner space enclosed by said outer frame thereof and an additional through hole is formed at an inner side of said wiring board so that said additional fitting member of said board mounting member is fitted into said additional through hole of said wiring board.
